(19) United States
(12) Patent Application Publication
(10) Pub. No.: US 2003/0117786 A1
(43) Pub. Date: Jun. 26, 2003

(54) Electromagnetic interference waveguide shield with absorber layer

(75) Inventors: Steve Y. Chang, West Linn, OR (US); Steven Y. Ji, Hillsboro, OR (US); Harry G. Skinner, Beaverton, OR (US); Howard L. Heck, Hillsboro, OR (US)

Correspondence Address: Schwegman, Lundberg, Woessner & Kluth, P.A., P.O. Box 2938, Minneapolis, MN, 55402, US

(73) Assignee: Intel Corporation

(21) Appl. No.: 10/027,345

(22) Filed: Dec. 20, 2001

(51) Int. Cl. H05K 9/00

(52) U.S. Cl. 361/818

(57) ABSTRACT

A waveguide shield for containing electromagnetic interference (EMI) is disclosed. The waveguide shield includes an array of waveguide cells. Each waveguide cell has a contiguous inner surface coated with an absorber layer that absorbs EMI over a select frequency range. Each waveguide cell also has an aperture. The waveguide shield can be combined with a metallic chassis covering portions of a computer that generate the EMI and heat. The absorber layer allows the waveguide cells to have apertures of a size that can contain the EMI within the chassis while also allowing the heat trapped within the chassis to escape.

### RELATED APPLICATIONS

This patent application is related to U.S. patent application Ser. No. ______, entitled “Method and apparatus for reducing electromagnetic leakage through chassis apertures,” filed on Jun. 26, 2001, and commonly assigned to the Assignee of the present application.

### FIELD OF THE INVENTION

The present invention relates to computers, and in particular relates to ventilation and electromagnetic interference (EMI) containment.

### BACKGROUND OF THE INVENTION

Modem computers include different types of circuits, including microprocessors and memory arrays, enclosed in a chassis. The microprocessors each include a central processing unit (CPU) that performs arithmetic and logic operations, and that controls the operation of the computer by decoding and executing sets of instructions.

The speed of the computer is dictated by the speed of CPU as determined by its “clock.” A clock is an oscillator circuit that generates a series of evenly spaced electrical pulses. The typical frequency of the clock pulses for present-day CPUs ranges from the megahertz (MHz) to gigahertz (GHz). Even higher frequencies are anticipated as integrated circuit technology advances.

The periodic emission of electrical signals by the clock results in the generation of electromagnetic radiation. If the metal chassis could be made without any apertures, the electromagnetic radiation generated by CPUs would be contained within the chassis. However, a significant amount of heat is generated by the flow of current through the numerous circuits, requiring ventilation apertures in the chassis. Unfortunately, typical ventilation apertures are large enough to allow electromagnetic radiation to escape the chassis. This radiation can detrimentally interact with electronic objects or humans residing near the computer, and is generally referred to as electromagnetic interference, or EMI. Accordingly, the Federal Communication Commission (FCC) places limits on the amount of EMI that can escape from a computer chassis.

As CPU clock speeds increase, the amounts of heat and EMI generated by the computer also increases. Further, the EMI frequencies include not only to the fundamental clock speed frequency, but also include high-frequency harmonics (e.g., 5×to 10×) of the fundamental. Consequently, EMI leakage can occur from increasingly smaller apertures. This in turn requires that the ventilation apertures in the computer chassis be made increasingly smaller to contain the EMI. However, the smaller apertures reduce ventilation capability, which can lead to overheating of the internal components of the computer.

To address this problem, vents in the form of metallic waveguide shields have been used to provide both ventilation and EMI protection. The waveguide shields are formed from an array of individual waveguide cells. The EMI leaving the chassis passes through the waveguide cells and interacts with the waveguide cell walls, which are made of metal and sometimes coated with a zinc-based paint for aesthetics. The EMI drives a surface current in the walls, which re-radiate at an attenuated level, thereby reducing the amount of outputted EMI. The waveguide apertures also allow heated air trapped in the chassis to escape.

FIG. 1 is a plot of the absolute radiation level Emax in decibel-microvolts/meter (dB-μV/m) versus EMI frequency in gigahertz (GHz) for a conventional metal waveguide shield coated with zinc paint, based on computer simulation. The plot illustrates that the conventional metal waveguide shield does not provide adequate EMI shielding above 4.5 GHz. With the advent of CPUs that operate in the GHz range and beyond, conventional waveguide shields will not be able to provide adequate protection from EMI without significantly reducing the size of the waveguide apertures. Unfortunately, since the faster CPUs generate more heat than slower CPUs, decreasing the size of the waveguide apertures to contain the EMI is not a viable option.

What is needed is a cost-effective EMI waveguide shield having apertures sized to provide adequate containment of high-frequency EMI within the computer chassis, but that also provide for adequate ventilation of the computer.

### BRIEF DESCRIPTION OF THE DRAWINGS

FIG. 1 is a plot based on computer simulation of the absolute radiation level Emax in decibel-microvolts/meter (dB-μV/m) versus EMI frequency in gigahertz (GHz) for a conventional metal waveguide shield with square waveguide cells coated with zinc paint, based on computer simulation;

FIG. 2 is a perspective view of a waveguide shield of the present invention having a rectangular body with rectangular waveguide cells;

FIG. 3A is a face-on view of a waveguide shield of the present invention having a circular body and circular waveguide cells;

FIG. 3B is a side view of the waveguide shield of FIG. 3A, showing three of the waveguide cells within the body;

FIG. 4A is a face-on view of a waveguide shield of the present invention having a rectangular body and circular waveguide cells;

FIG. 4B is a side view of the waveguide shield of FIG. 4A, showing three of the waveguide cells within the body;

FIG. 5A is a face-on view of a waveguide shield of the present invention having a triangular body and triangular waveguide cells;

FIG. 5B is a side view of the waveguide shield of FIG. 5A, showing three of the waveguide cells within the body;

FIG. 6 is a close-up side view of a portion of a waveguide cell of the waveguide shield of the present invention, showing the EMI absorber layer formed on the waveguide cell inner surface;

FIG. 7 is a plot illustrating the relative maximum electric field Emax (dB) for the same waveguide as for FIG. 1, but with an EMI absorber layer with a resistivity of 900 Ohms/square covering the inner surface of each waveguide cell (line with squares), and wherein the baseline of 0 dB (line with circles) is that for the zinc-painted waveguide of FIG. 1;

FIG. 8A is a partial cut-away perspective view of a computer chassis housing the central processing units (CPUs) of a computer, showing the waveguide shield of FIG. 2 attached to the chassis; and

FIG. 8B is a cross-sectional view of the apparatus of FIG. 8A, showing the waveguide shield blocking the EMI while allowing heat to escape from the chassis.

### DETAILED DESCRIPTION OF THE INVENTION

In the following detailed description of the embodiments of the invention, reference is made to the accompanying drawings that form a part hereof, and in which is shown by way of illustration specific embodiments in which the invention may be practiced. These embodiments are described in sufficient detail to enable those skilled in the art to practice the invention, and it is to be understood that other embodiments may be utilized and that changes may be made without departing from the scope of the present invention. The following detailed description is, therefore, not to be taken in a limiting sense, and the scope of the present invention is defined only by the appended claims.

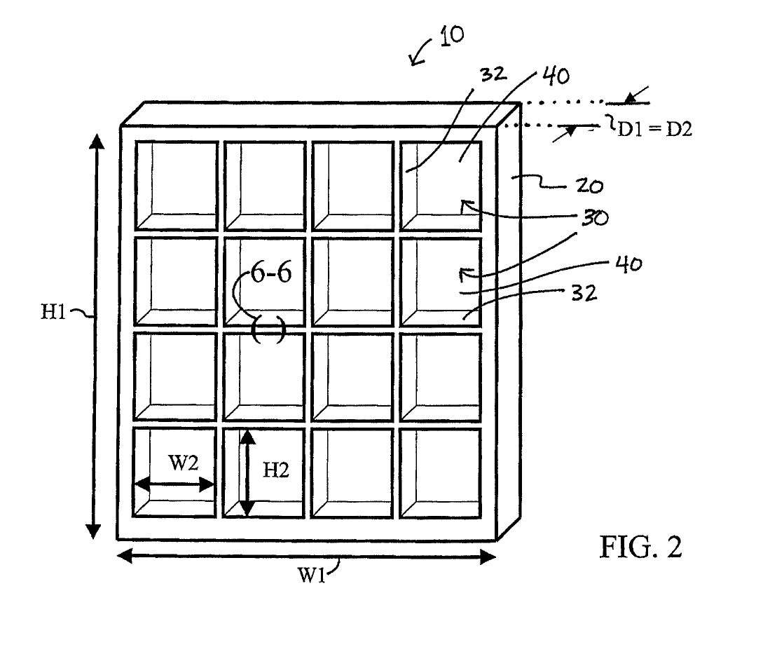

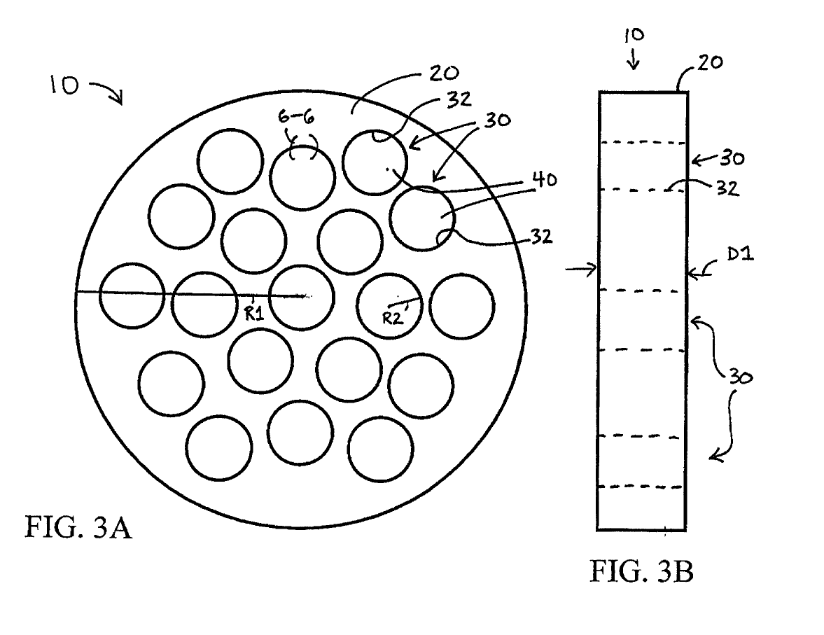

FIGS. 2, 3A,B, 4A,B and 5A,B illustrate different embodiments of a waveguide shield 10. Waveguide shield 10 generally has a body 20 that includes an array of waveguide cells 30. Each waveguide cell 30 has a contiguous inner surface 32 and an associated aperture 40. Body 20 and waveguide cells 30 can each have any one of a number of cross-sectional shapes, such as circular or polygonal. The waveguide cells can be assembled together to form the body. Alternatively, the body can be molded to form the waveguide cells. Further, the waveguide cells can be machined from or drilled out of the body. Thus, in one embodiment the waveguide body defines the waveguide cells, while in another embodiment the waveguide cells define the waveguide body.

In one example embodiment, body 20 is metal, such as aluminum. In another example embodiment, body 20 is an insulator, such as molded plastic, sheet plastic, rigid polymer, composite material, ceramic, glass or wood. An insulating body is advantageous because it does not support the re-radiating surface currents that occur in a metal body. An insulating body is also advantageous because it can be more lightweight and inexpensive than a metal body.

In the example embodiment of waveguide shield 10 illustrated in FIG. 2, body 20 is a rectangular cylinder of height H1, width W1 and depth D1. Waveguide cells 30 are also rectangular, with each cell having a height H2, a width W2 and a depth D2=D1. In another similar example embodiment, body 20 is square and waveguide cells 30 are square. In a specific example, body 20 has a width W1=37 cm, height H1=36 cm and depth D1=2.0 cm, while each waveguide cell has dimensions W2=H2=2.5 cm and D2=2.0 cm.

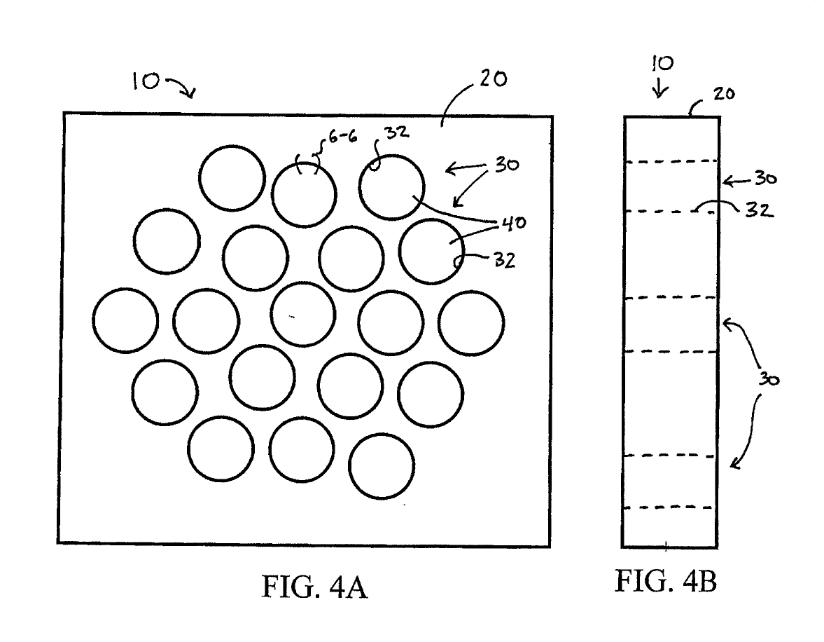

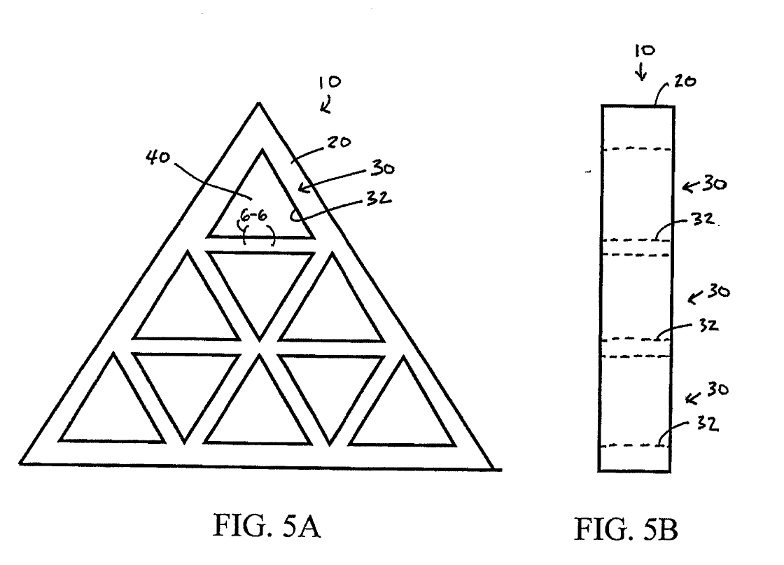

In another example embodiment illustrated in FIGS. 3A and 3B, body 20 is a circular cylinder of depth D1 and radius R1, with circular cylinder waveguides 30 of radius R2 and depth D1. In another example embodiment illustrated in FIGS. 4A and 4B, waveguide shield 10 has a rectangular body with circular cylinder waveguide cells. In yet another example embodiment illustrated in FIGS. 5A and 5B, waveguide shield 10 has a triangular body with triangular cylinder waveguide cells. These are just a few of the possible geometries of waveguide shield 10, and it will apparent to one skilled in the art that the waveguide shield of the present invention is not limited by the particular shapes of the waveguide cells and waveguide body.

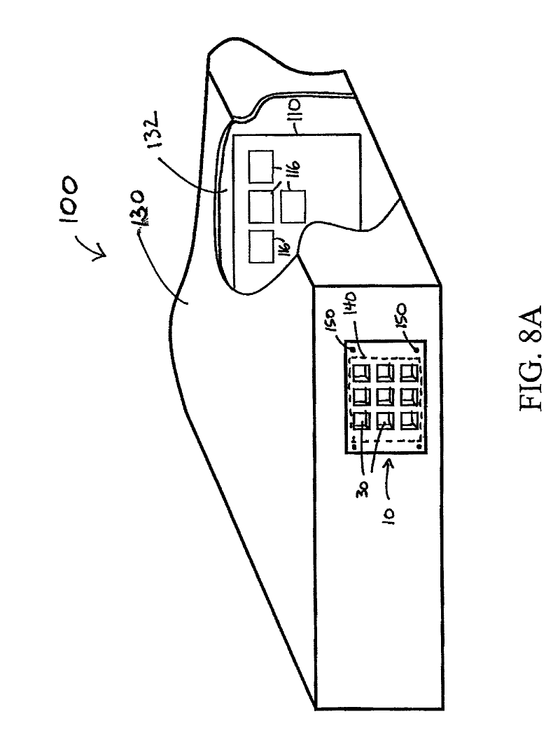

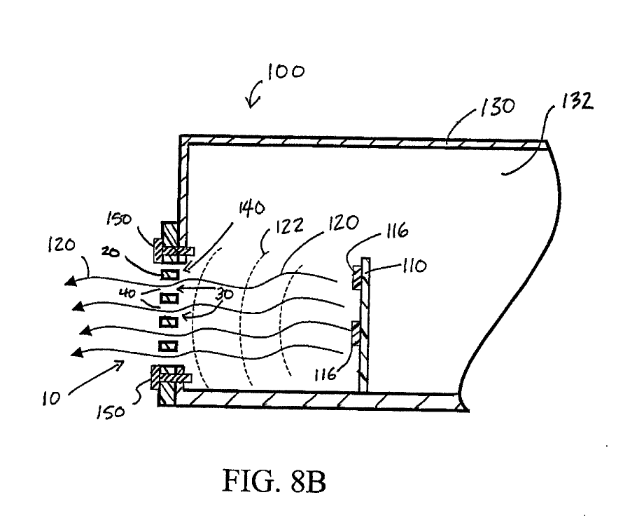

Regardless of the waveguide shield geometry, waveguide cells 30 are sized to ensure that apertures 40 provide both adequate blockage of EMI as well as adequate ventilation when the waveguide shield is attached to a computer chassis, as described below in connection with FIGS. 8A and 8B.

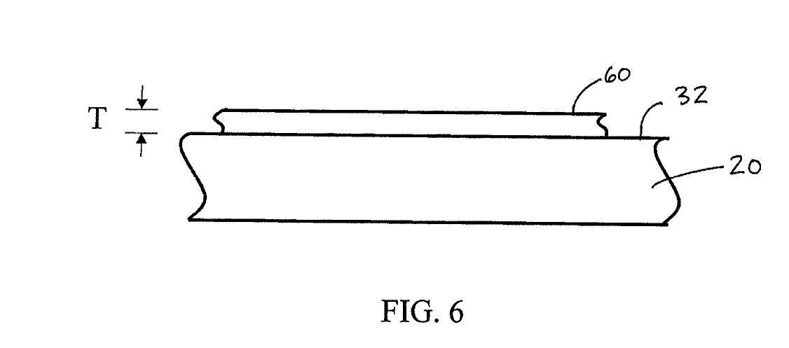

FIG. 6 is a close-up side view of a portion of a typical waveguide cell 20. An EMI absorber layer 60 of thickness T covers at least a portion of each inner surface 32 of each waveguide cell. In an example embodiment, absorber layer 60 covers the entire inner surface. Absorber layer 60 operates to absorb electromagnetic radiation in the select frequency range of EMI. In an example embodiment, the select frequency range includes MHz and GHz frequencies. Absorber layer 60 may be a single layer, or may include multiple layers of different EMI absorbing materials. In an example embodiment, EMI absorber layer is an epoxy resin filled with particles having a high magnetic loss tangent in the EMI frequency range. A suitable material for absorber layer 60 is called C-RAM and is available from Cuming Microwave Corporation, 225 Bodwell Street, Avon, Mass. 02332.

Absorber layer 60 may be sprayed on inner surface 32 to form a thin layer and to ensure adhesion. Absorber layer 60 may also be brushed on. Alternatively, body 20 may be masked except for some or all of inner surfaces 32 and then dipped into a bath of absorber layer material to simultaneously coat some or all of the inner surfaces. Dipping may require diluting the absorber material so that the select thickness T is obtained. Multiple dippings may be used to build up layers to achieve the select thickness T. Absorber layer 60 may also be in the form of a sheet fixed to inner surface 32.

In an example embodiment, the absorber layer has a thickness T in the range from about 1 to about 10 mils, i.e., about 0.025 mm to about 0.25 mm. Generally, the higher the frequency of the EMI, the thinner EMI absorber layer 60 can be. The precise thickness T required to sufficiently absorb radiation over a given frequency range can be readily determined empirically or by simulation. In another example embodiment, absorber layer 60 has a resistivity in the range from about 200 Ohms/square to about 1200 Ohms/square.

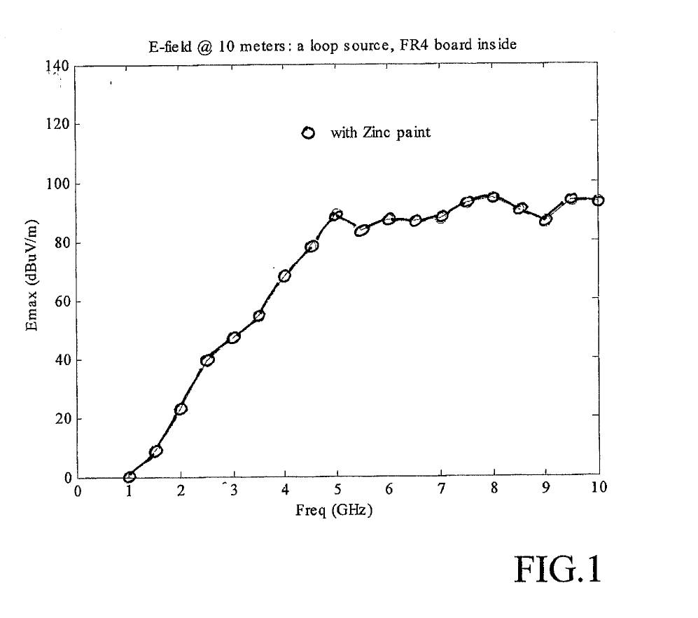

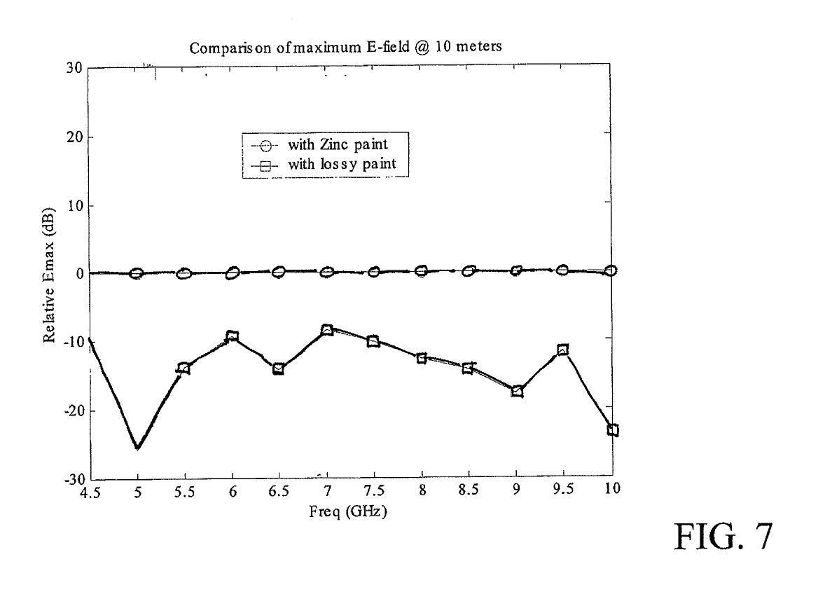

FIG. 7 plots the relative maximum electric field Emax in decibels (dB) versus the EMI frequency in GHz for the same waveguide shield considered in FIG. 1, except that the zinc coating was replaced with an absorber layer with a resistivity of 900 Ohms/square. The waveguide shield has a rectangular body dimensions H1=37 cm, W1=36 cm, D1=2.0 cm and square waveguide cell dimensions of H2=W2=2.5 cm and D2=D1=2.0 cm.

It is seen in FIG. 7 that the waveguide shield with the absorber layer has significant EMI benefits over a relatively large frequency range (i.e., at least from 4.5 GHz to 10 GHz). This is advantageous because the waveguide cell apertures 40 do not need to be made smaller to maintain EMI shielding effectiveness as the EMI frequency increases. Accordingly, adequate ventilation of heat generated by the computer can be realized without comprising EMI containment.

FIGS. 8A and 8B show a computer 100 with a motherboard 110 to which is fixed CPUs chips 116, which emit heat 120 and EMI 122. A chassis 130 defining an interior 132 covers the motherboard and includes a main aperture 140 for ventilation. Chassis 130 is preferably metal so that it acts as a natural shield to EMI. A waveguide shield 10 is then attached to the chassis at aperture 40 to provide for substantial containment of EMI. In an example embodiment, waveguide shield 10 is attached to chassis 130 by screws 150. The waveguide shield can be fixed to the outside of the chassis (as shown), to the inside of the chassis, or directly within the main aperture.

The combination of chassis 130 and waveguide shield 10 of the present invention serves to substantially contain EMI 122 over a wide range of select EMI frequencies. Further, use of waveguide shield 10 provides for effective ventilation of heat 120 trapped in interior 132 through main aperture 140 via the waveguide cell apertures 40. This is because the waveguide cell apertures do not need to be reduced in size to shield the EMI as compared to the apertures of conventional waveguide shields. In addition, because body 20 of waveguide 10 need not be metal, waveguide shield 10 can be cost-effective and lightweight and insusceptable to surface currents that can re-radiate the EMI.

While the present invention has been described in connection with preferred embodiments, it will be understood that it is not so limited. On the contrary, it is intended to cover all alternatives, modifications and equivalents as may be included within the spirit and scope of the invention as defined in the appended claims.

What is claimed is:

1. An electromagnetic interference (EMI) shield comprising:
a waveguide body including an array of waveguide cells each having a contiguous inner surface; and
an absorber layer covering at least a portion of each contiguous inner surface and capable of absorbing electromagnetic radiation over a select frequency range.

2. The shield of claim 1, wherein each waveguide cell has a polygonal cross-section.

3. The shield of claim 1, wherein each waveguide cell has a circular cross-section.

4. The shield of claim 1, wherein the polygonal cross-sectional shape is rectangular.

5. The shield of claim 1, wherein the absorber layer covers the entire contiguous inner surface.

6. The shield of claim 1, wherein the absorber layer has a thickness between about 0.025 millimeters to about 0.25 millimeters.

7. The shield of claim 1, wherein the absorber layer has a resistivity between about 200 Ohms/square and about 1200 Ohms/square.

8. The shield of claim 1, wherein the waveguide body is formed of an insulating material.

9. The shield of claim 8, wherein the insulating material is one selected from the group of materials consisting of: plastic, polymer, composite material, ceramic, wood and glass.

10. The shield of claim 1, wherein the select frequency range includes frequencies in the megahertz (MHz) range and the gigahertz (GHz) range.

11. The shield of claim 1, wherein the absorber layer includes an epoxy resin filled with particles having a high magnetic loss over the select frequency range.

12. The shield of claim 1, wherein the body is formed of metal.

13. An electromagnetic interference (EMI) shield, comprising:
an array of waveguide cells each having a contiguous inner surface;
an absorber layer covering at least a portion of each contiguous inner surface, the absorber layer capable of absorbing electromagnetic radiation over a select frequency range.

14. The shield of claim 13, wherein the absorber layer entirely covers each contiguous inner surface.

15. The shield of claim 13, wherein the waveguide cells have a cross-sectional shape that is one of polygonal and circular.

16. The shield of claim 13, wherein the waveguide cells are formed from an insulator.

17. The shield of claim 13, wherein the absorber layer has a thickness between about 0.025 millimeters to about 0.25 millimeters.

18. The shield of claim 13, wherein the select frequency range includes frequencies in the megahertz (MHz) range and the gigahertz (GHz) range.

19. An electromagnetic interference (EMI) shield for a computer, comprising:
a metal chassis having an aperture, the chassis adapted to enclose portions of the computer that generates heat and EMI over a select frequency range; and
an EMI waveguide shield fixed to the chassis and covering the aperture, the EMI waveguide shield including an array of waveguide cells each having a contiguous inner surface, and an absorber layer covering at least a portion of each contiguous inner surface, the absorber layer capable of absorbing the EMI.

20. The EMI shield of claim 13, wherein each waveguide cell has an associated aperture that allows heat to pass therethrough.

21. The EMI shield of claim 19, further comprising the computer.

22. The EMI shield of claim 19, wherein the waveguide shield includes a body formed from an insulator.

23. A method of reducing electromagnetic interference (EMI) from a computer, comprising:
enclosing portions of the computer that generate heat and EMI over a select frequency range with a metal chassis having an interior;
introducing the EMI and heat to an array of waveguide cells fixed to the chassis, each waveguide cell having an aperture leading from the interior and a contiguous inner surface at least partially coated with an absorber layer that absorbs the EMI over the select frequency range; and absorbing the EMI with the absorber layer to substantially contain the EMI within the interior, while allowing the heat to pass from the interior through each aperture.

24. The method of claim 23, further including covering the entirety of each inner surface with the absorber layer.

25. The method of claim 23, including forming the absorber layer to have a thickness between about 0.025 millimeters and 0.25 millimeters.

26. The method of claim 23, including fixing the waveguide cells to the chassis with screws.
